(19) United States
(12) Patent Application Publication
(10) Pub. No.: US 2019/0296168 A1
(43) Pub. Date: Sep. 26, 2019

(54) THIN FILM SOLAR CELLS AND METHODS OF MAKING THEREOF

(71) Applicants: THE BOARD OF TRUSTEES OF THE UNIVERSITY OF ALABAMA, Tuscaloosa, AL (US); The Texas A&M University System, College Station, TX (US)

(72) Inventors: Feng Yan, Tuscaloosa, AL (US); Lin Li, Tuscaloosa, AL (US); Xiaofeng Qian, College Station, TX (US)

(21) Appl. No.: 16/352,184

(22) Filed: Mar. 13, 2019

Related U.S. Application Data
(60) Provisional application No. 62/645,977, filed on Mar. 21, 2018.

(51) Int. Cl. H01L 31/0445; H01L 31/0224; H01L 31/0304; H01L 31/18

(52) U.S. Cl. CPC H01L 31/0445; H01L 31/022466; H01L 31/18; H01L 31/03044; H01L 31/022425

(57) ABSTRACT

Disclosed herein are thin film solar cells comprising antimony chalcogenide layers deposited via close spaced sublimation, and methods of making thereof.

### CROSS-REFERENCE TO RELATED APPLICATIONS

This application claims the benefit of priority to U.S. Provisional Application No. 62/645,977, filed Mar. 21, 2018, which is hereby incorporated herein by reference in its entirety.

### BACKGROUND

Current thin film solar cell technology relies on materials that are toxic, expensive, require high energy consumption during production, have a limited supply, and/or have a low efficiency. Thin film solar cells comprising materials that are relatively non-toxic, less expensive, earth abundant, require lower energy consumption during production, are readily available, and/or have higher efficiency are needed. Further, methods of making such thin film solar cells that are scalable are needed. The thin film solar cells and methods of making thereof described herein address these and other needs.

### SUMMARY

Disclosed herein are thin film solar cells comprising antimony chalcogenide layers deposited via close spaced sublimation, and methods of making thereof.

Additional advantages will be set forth in part in the description that follows, and in part will be obvious from the description, or may be learned by practice of the aspects described below. The advantages described below will be realized and attained by means of the elements and combinations particularly pointed out in the appended claims. It is to be understood that both the foregoing general description and the following detailed description are exemplary and explanatory only and are not restrictive.

The details of one or more embodiments of the invention are set forth in the accompanying figures and the description below. Other features, objects, and advantages of the invention will be apparent from the description, figures, and claims.

### BRIEF DESCRIPTION OF FIGURES

The accompanying drawings, which are incorporated and constitute a part of this specification, illustrate several aspects of the disclosure, and together with the description, serve to explain the principles of the disclosure.

FIG. 1 is a schematic diagram of an example thin film solar cell.

FIG. 2 is a photograph of an example thin film solar cell.

FIG. 3 is a schematic diagram of a close spaced sublimation (CSS) set up.

FIG. 4 shows photographs of the initial substrate, the CdS coated substrate, and the substrate after deposition of the Sb₂Se₃.

FIG. 5 is the X-ray diffraction (XRD) spectra for the Sb₂Se₃ films deposited at various temperatures.

FIG. 6 is the XRD spectra for the Sb₂Se₃ films of various thicknesses.

FIG. 7a is the current-voltage curves of two solar cells with different film thicknesses.

FIG. 7b is the EQE data corresponding to the current-voltage curves shown in FIG. 7a.

### DETAILED DESCRIPTION

The devices and methods described herein may be understood more readily by reference to the following detailed description of specific aspects of the disclosed subject matter, figures and the examples included therein.

Before the present devices and methods are disclosed and described, it is to be understood that the aspects described below are not intended to be scope by the specific systems, methods, articles, and devices described herein, which are intended as illustrations. Various modifications of the systems, methods, articles, and devices in addition to those shown and described herein are intended to fall within the scope of that described herein. Further, while only certain representative systems and method steps disclosed herein are specifically described, other combinations of the systems and method steps also are intended to fall within the scope of that described herein, even if not specifically recited. Thus, a combination of steps, elements, components, or constituents may be explicitly mentioned herein or less, however, other combinations of steps, elements, components, and constituents are included, even though not explicitly stated.

The term “comprising” and variations thereof as used herein is used synonymously with the term “including” and variations thereof and are open, non-limiting terms. Although the terms “comprising” and “including” have been used herein to describe various examples, the terms “consisting essentially of” and “consisting of” can be used in place of “comprising” and “including” to provide for more specific examples of the invention and are also disclosed. Other than in the examples, or where otherwise noted, all numbers expressing quantities of ingredients, reaction conditions, and so forth used in the specification and claims are to be understood at the very least, and not as an attempt to limit the application of the doctrine of equivalents to the scope of the claims, to be construed in light of the number of significant digits and ordinary rounding approaches.

As used in the description and the appended claims, the singular forms “a,” “an,” and “the” include plural referents unless the context clearly dictates otherwise. Thus, for example, reference to “a composition” includes mixtures of two or more such compositions, reference to “an agent” includes mixtures of two or more such agents, reference to “the component” includes mixtures of two or more such components, and the like.

“Optional” or “optionally” means that the subsequently described event or circumstance can or cannot occur, and that the description includes instances where the event or circumstance occurs and instances where it does not.

It is understood that throughout this specification the identifiers “first”, “second” and “third” are used solely to aid in distinguishing the various components and steps of the disclosed subject matter. The identifiers “first”, “second” and “third” are not intended to imply any particular order, amount, preference, or importance to the components or steps modified by these terms.

Also, throughout this specification, various publications are referenced. The disclosures of these publications in their entireties are hereby incorporated by reference into this application in order to more fully describe the state of the art to which the disclosed matter pertains. The references disclosed are also individually and specifically incorporated by reference herein for the material contained in them that is discussed in the sentence in which the reference is relied upon.

Terms used herein will have their customary meaning in the art unless specified otherwise.

Reference will now be made in detail to specific aspects of the disclosed materials, compounds, compositions, articles, and methods, examples of which are illustrated in the accompanying examples and figures.

Thin Film Solar Cells and Methods of Making Thereof Disclosed herein are thin film solar cells comprising a first electrode comprising a transparent conducting oxide. The transparent conducting oxides can, for example, comprise indium doped tin oxide (ITO), fluorine doped tin oxide (FTO), aluminum doped ZnO (AZO), or a combination thereof.

The thin film solar cells further comprise a buffer layer disposed on the first electrode. The buffer layer can comprise, for example, a metal sulfide, a metal oxide, or a combination thereof. In some examples, the buffer layer can comprise CdS, SnO, ZnO, TiO₂, or a combination thereof. In some examples, the buffer layer can comprise CdS.

The buffer layer can, for example, have an average thickness of 20 nm or more (e.g., 30 nm or more, 40 nm or more, 50 nm or more, 60 nm or more, 70 nm or more, 80 nm or more, 90 nm or more, 100 nm or more, 110 nm or more, 120 nm or more, 130 nm or more, 140 nm or more, 150 nm or more, 200 nm or more, 250 nm or more, 300 nm or more, 350 nm or more, 400 nm or more, 450 nm or more, 500 nm or more, 600 nm or more, 700 nm or more, or 800 nm or more). In some examples, the buffer layer can have an average thickness of 1000 nm or less (e.g., 900 nm or less, 800 nm or less, 700 nm or less, 600 nm or less, 500 nm or less, 450 nm or less, 400 nm or less, 350 nm or less, 300 nm or less, 250 nm or less, 200 nm or less, 150 nm or less, 140 nm or less, 130 nm or less, 120 nm or less, 110 nm or less, 100 nm or less, 90 nm or less, 80 nm or less, 70 nm or less, 60 nm or less, 50 nm or less, or 40 nm or less). The average thickness of the buffer layer can range from any of the minimum values described above to any of the maximum values described above. The buffer layer can, for example, have an average thickness of from 20 nm to 1000 nm (e.g., from 20 nm to 500 nm, from 500 nm to 1000 nm, from 20 nm to 200 nm, from 200 nm to 400 nm, from 400 nm to 600 nm from 600 nm to 800 nm, from 800 nm to 1000 nm, from 20 nm to 800 nm, from 20 nm to 600 nm, from 20 nm to 400 nm, from 20 nm to 200 nm, from 50 nm to 150 nm, or from 90 nm to 110 nm).

The thin film solar cells further comprise an antimony chalcogenide layer deposited via close spaced sublimation on the buffer layer, such that the buffer layer is disposed between the antimony chalcogenide layer and the first electrode (e.g., such that the buffer layer is substantially sandwiched between the antimony chalcogenide layer and the first electrode). The antimony chalcogenide layer can comprise an antimony chalcogenide of the formula Sb₂SₓSe₃₋ₓ wherein x can be any value from 0 to 3 (e.g., 0, 0.25, 0.5, 0.75, 1, 1.25, 1.5, 1.75, 2, 2.25, 2.5, 2.75, or 3). In some examples, the antimony chalcogenide layer comprises Sb₂Se₃, Sb₂S₃, or a combination thereof.

The antimony chalcogenide layer can, for example, have an average thickness of 0.1 μm or more (e.g., 0.2 μm or more, 0.3 μm or more, 0.4 μm or more, 0.5 μm or more, 0.6 μm or more, 0.7 μm or more, 0.8 μm or more, 0.9 μm or more, 1 μm or more, 1.1 μm or more, 1.2 μm or more, 1.3 μm or more, 1.4 μm or more, 1.5 μm or more, 1.6 μm or more, 1.7 μm or more, 1.8 μm or more, 1.9 μm or more, 2 μm or more, 2.25 μm or more, 2.5 μm or more, 2.75 μm or more, 3 μm or more, 3.25 μm or more, 3.5 μm or more, 3.75 μm or more, 4 μm or more, 4.25 μm or more, or 4.5 μm or more). In some examples, the antimony chalcogenide layer can have an average thickness of 5 μm or less (e.g., 4.75 μm or less, 4.5 μm or less, 4.25 μm or less, 4 μm or less, 3.75 μm or less, 3.5 μm or less, 3.25 μm or less, 3 μm or less, 2.75 μm or less, 2.5 μm or less, 2.25 μm or less, 2 μm or less, 1.9 μm or less, 1.8 μm or less, 1.7 μm or less, 1.6 μm or less, 1.5 μm or less, 1.4 μm or less, 1.3 μm or less, 1.2 μm or less, 1.1 μm or less, 1 μm or less, 0.9 μm or less, 0.8 μm or less, 0.7 μm or less, 0.6 μm or less, 0.5 μm or less, 0.4 μm or less, or 0.3 μm or less). The average thickness of the antimony chalcogenide layer can range from any of the minimum values described above to any of the maximum values described above. The antimony chalcogenide layer can, for example, have an average thickness of from 0.1 μm to 5 μm (e.g., from 0.1 μm to 2.5 μm, from 2.5 μm to 5 μm, from 0.1 μm to 1 μm, from 1 μm to 2 μm, from 2 μm to 3 μm, from 3 μm to 4 μm, from 4 μm to 5 μm, from 0.1 μm to 4 μm, from 0.3 μm to 3 μm, or from 0.6 μm to 2 μm).

The thin film solar cells further comprise a second electrode in electrical contact with the antimony chalcogenide layer, such that the antimony chalcogenide layer is disposed between (e.g., substantially sandwiched by) the second electrode and the buffer layer. The second electrode can, for example, comprise graphite, Cu/Al or other high work function metals.

The thin film solar cells can have an efficiency of 4% or more (e.g., 5% or more, 6% or more, 7% or more, 8% or more, 9% or more, 10% or more, 15% or more, 20% or more, 25% or more, or 30% or more). For example, the thin film solar cell can have an efficiency of from 4% to 32%.

Also disclosed herein are methods of making the thin film solar cells described herein. The methods can comprise depositing the buffer layer on the first electrode, thereby forming a coated electrode. The buffer layer can, for example, be deposited by chemical bath deposition, physical vapor deposition, atomic layer deposition, spray pyrolysis or chemical vapor deposition. In some examples, the methods can further comprise annealing the buffer layer before depositing the antimony chalcogenide layer.

The methods further comprise depositing the antimony chalcogenide layer on the buffer layer via close spaced sublimation. An antimony chalcogenide source can be used during the close spaced sublimation deposition.

In some examples, the antimony chalcogenide source can have a temperature of 200° C. or more during the close spaced sublimation deposition (e.g., 225° C. or more, 250° C. or more, 275° C. or more, 300° C. or more, or 325° C. or more). In some examples, the antimony chalcogenide source can have a temperature of 350° C. or less during the close spaced sublimation deposition (e.g., 325° C. or less, 300° C. or less, 275° C. or less, 250° C. or less, or 225° C. or less). The temperature of the antimony chalcogenide source during close spaced sublimation deposition can range from any of the minimum values described above to any of the maximum values described above. In some examples, the antimony chalcogenide source has a temperature of from 200° C. to 350° C. during the close spaced sublimation deposition (e.g., from 200° C. to 275° C., from 275° C. to 350° C., from 200° C. to 250° C., from 250° C. to 300° C., from 300° C. to 350° C., or from 225° C. to 325° C.).

In some examples, the antimony chalcogenide source (e.g., powder) can have a temperature of 450° C. or more during the close spaced sublimation deposition (e.g., 475° C. or more, 500° C. or more, 525° C. or more, 550° C. or more, or 575° C. or more). In some examples, the antimony chalcogenide source (e.g., powder) can have a temperature of 600° C. or less during the close spaced sublimation deposition (e.g., 575° C. or less, 550° C. or less, 525° C. or less, 500° C. or less, or 475° C. or less). The temperature of the antimony chalcogenide source (e.g., powder) during close spaced sublimation deposition can range from any of the minimum values described above to any of the maximum values described above. In some examples, the antimony chalcogenide source (e.g., powder) can have a temperature of from 450° C. to 600° C. during the close spaced sublimation deposition (e.g., from 450° C. to 525° C., from 525° C. to 600° C., from 450° C. to 500° C., from 500° C. to 550° C., from 550° C. to 600° C., or from 475° C. to 575° C.).

The antimony chalcogenide layer can, for example, be deposited via closed spaced sublimation at a pressure of 1 mTorr or more (e.g., 5 mTorr or more, 10 mTorr or more, 15 mTorr or more, 20 mTorr or more, 25 mTorr or more, 30 mTorr or more, 40 mTorr or more, 50 mTorr or more, 60 mTorr or more, 70 mTorr or more, or 80 mTorr or more). In some examples, the antimony chalcogenide layer can be deposited via closed spaced sublimation at a pressure of 100 mTorr or less (e.g., 90 mTorr or less, 80 mTorr or less, 70 mTorr or less, 60 mTorr or less, 50 mTorr or less, 40 mTorr or less, 30 mTorr or less, 25 mTorr or less, 20 mTorr or less, 15 mTorr or less, or 10 mTorr or less). The pressure at which the antimony chalcogenide layer is deposited via close spaced sublimation can range from any of the minimum values described above to any of the maximum values described above. The antimony chalcogenide layer can, for example, be deposited via closed spaced sublimation at a pressure of from 1 mTorr to 100 mTorr (e.g., from 1 mTorr to 50 mTorr, from 50 mTorr to 100 mTorr, from 1 mTorr to 20 mTorr, from 20 mTorr to 40 mTorr, from 40 mTorr to 60 mTorr, from 60 mTorr to 80 mTorr, from 80 mTorr to 100 mTorr, from 5 mTorr to 95 mTorr, or from 10 mTorr to 90 mTorr).

In some examples, the antimony chalcogenide layer is deposited via close spaced sublimation for 30 seconds or more for various thickness (e.g., 35 seconds or more, 40 seconds or more, 45 seconds or more, 50 seconds or more, 55 seconds or more, 60 seconds or more, 70 seconds or more, 80 seconds or more, 90 seconds or more, or 100 seconds or more). In some examples, the antimony chalcogenide layer is deposited via close spaced sublimation for 120 seconds or less for various thickness (e.g., 110 seconds or less, 100 seconds or less, 90 seconds or less, 80 seconds or less, 70 seconds or less, 60 seconds or less, 55 seconds or less, 50 seconds or less, 45 seconds or less, or 40 seconds or less). The time for which the antimony chalcogenide layer is deposited via close spaced sublimation for various thickness can range from any of the minimum values described above to any of the maximum values described above. In some examples, the antimony chalcogenide layer is deposited via close spaced sublimation for from 30 seconds to 120 seconds for various thickness (e.g., from 30 seconds to 70 seconds, from 70 seconds to 120 seconds, from 30 seconds to 60 seconds, from 60 seconds to 90 seconds, from 90 seconds to 120 seconds, from 40 seconds to 110 seconds, or from 45 seconds to 105 seconds).

The methods can further comprise disposing the second electrode on the antimony chalcogenide layer.

### EXAMPLES

The following examples are set forth below to illustrate the methods and results according to the disclosed subject matter. These examples are not intended to be inclusive of all aspects of the subject matter disclosed herein, but rather to illustrate representative methods and results. These examples are not intended to exclude equivalents and variations of the present invention which are apparent to one skilled in the art.

Efforts have been made to ensure accuracy with respect to numbers (e.g., amounts, temperature, etc.) but some errors and deviations should be accounted for. Unless indicated otherwise, parts are parts by weight, temperature is in ° C. or is at ambient temperature, and pressure is at or near atmospheric. There are numerous variations and combinations of reaction conditions, e.g., component concentrations, temperatures, pressures and other reaction ranges and conditions that can be used to optimize the product purity and yield obtained from the described process. Only reasonable and routine experimentation will be required to optimize such process conditions.

### Example 1

Current thin film solar cell technology relies on materials that are toxic (e.g., Pb, Cd, As), expensive (e.g., Ga), require high energy consumption during production (e.g., Si), have a limited supply (e.g., Te), and/or have a low efficiency (e.g., BaSi₂, CuO₂).

Meanwhile, Antimony (Sb), Sulfur (S), and Selenium (Se) are environmentally friendly and relatively non-toxic, are relatively cheap, have a relatively high abundance, and have lower melting points and deposition temperatures, leading to reduced energy consumption during manufacturing.

Described herein are low-cost, scalable, antimony chalcogenide (e.g., Sb₂SₓSe₃₋ₓ wherein x is from 0 to 3) based thin film solar cells, wherein the antimony chalcogenide thin film was deposited using close spaced sublimation. The thin film solar cells further comprise a buffer layer comprising a sulfide and/or oxide (e.g., CdS, SnO, ZnO, etc.). The antimony chalcogenide thin film solar cells fabricated using close spaced sublimation exhibit improved efficiency. The materials cost of the antimony chalcogenides is much lower than the traditional CdTe, and the energy consumption is lower due to the lower sublimation temperature of the antimony chalcogenides relative to CdTe. Hence, the overall manufacturing cost is lower relative to CdTe. Moreover, the close spaced sublimation synthesis method is scalable and compatible with large-scale commercialization of the thin film solar cells.

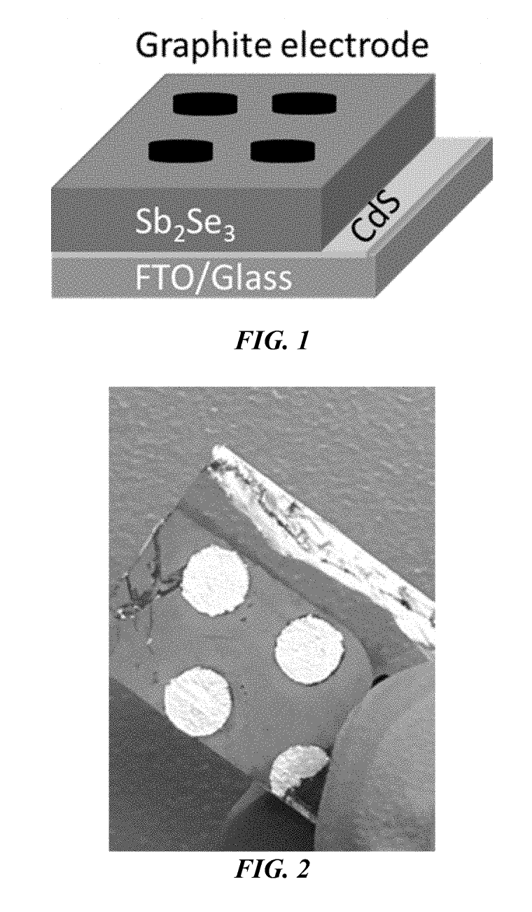

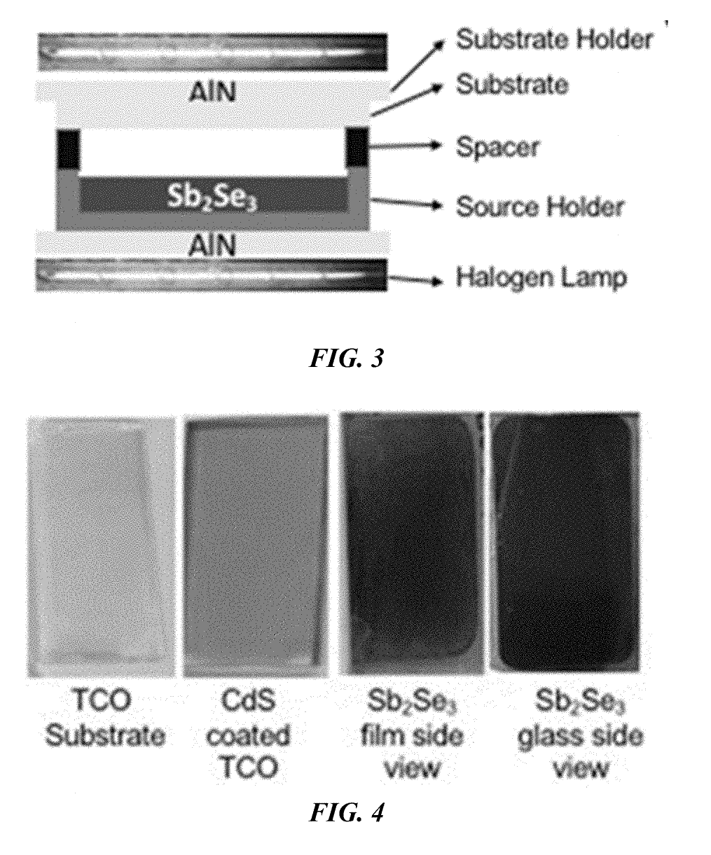

A schematic diagram of an example thin film solar cell as described herein is shown in FIG. 1. A photograph of an example device is shown in FIG. 2. About 100 nm thick CdS window layers were deposited on a cleaned FTO coated soda-lime glass (Pilkington, US) by chemical bath deposition (CBD) at a bath temperature of 70° C. The CdS film was annealed at 400° C. for 30 min to improve the crystallization. Sb₂Se₃ thin film with thickness of 0.6 to 2 μm were grown in Ar ambient using a commercial close spaced sublimation (CSS) system (MTI, US). The high purity Sb₂Se₃ (99.999%, Alfa Aesar, US) was placed on the bottom AlN plate, and the CdS coated FTO substrate was loaded on the top AlN plate (5 mm distance from the Sb₂Se₃ powder) (FIG. 3). To optimize the growth conditions of Sb₂Se₃ absorbers, the substrate and source temperatures were varied from 250° C. to 350° C., and 500° C. to 580° C., respectively at chamber pressure about 1 to 10 mTorr. The Sb₂Se₃ thin film thickness was controlled via manipulating the deposition time from 30 to 100 seconds, then switching off the halogen lamp heater and cooling the film naturally to room temperature. Photographs of the initial substrate, the CdS coated substrate, and the substrate after deposition of the Sb₂Se₃ are shown in FIG. 4. The as-grown Sb₂Se₃ films were cleaned with deionized water rinse and then graphite and Ag paste was screen printed on the Sb₂Se₃ (with active area of 0.08 cm²), respectively to define the solar cells.

Materials Characterization:

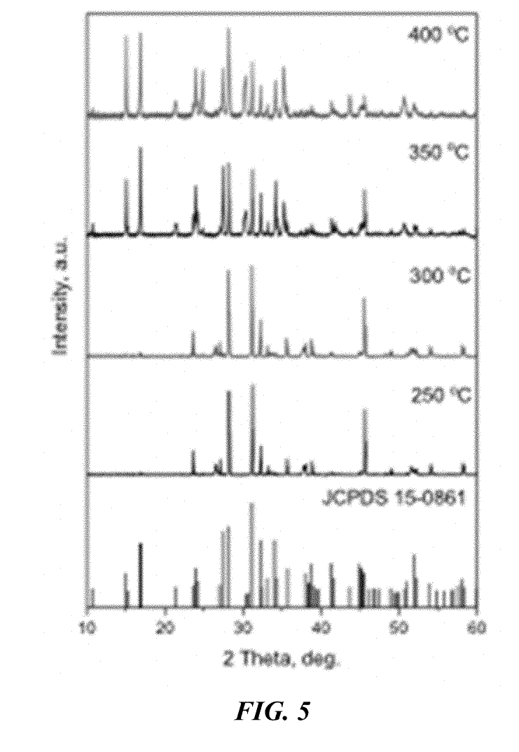

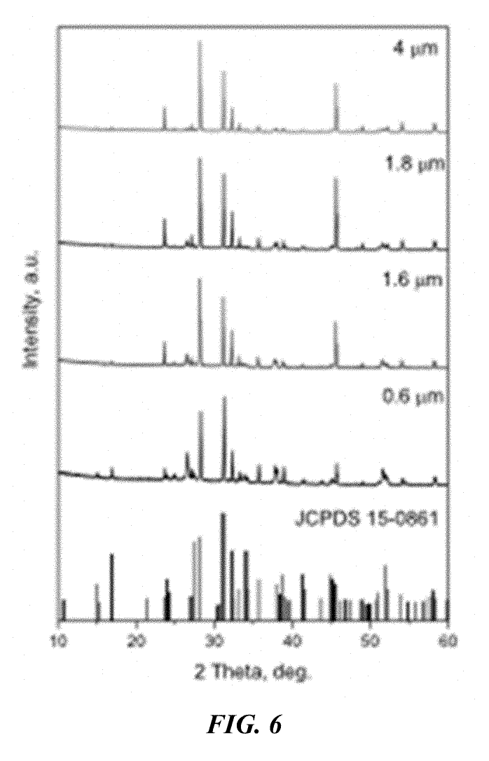

The film thickness was determined by the surface profilometer (Dektak II). The structure of the grown films was performed by a X-ray diffraction System (X'Pert). The film morphologies and chemical composition were determined by the scanning electron microscope (SEM, JEOL 7000) with Electron-dispersive Spectroscopy (EDS) attached to the SEM. EDS spectra for the Sb₂Se₃ films deposited at various temperatures and at various thickness are shown in FIG. 5 and FIG. 6, respectively. The Raman experiments were conducted on a single stage Raman spectrometer with a solid-state laser (Horiba LabRam HR, 532 nm wavelength). The absorbance and transmittance spectra were measured using a UV-Vis spectrometer (Shimadzu UV-1800). The AFM and conductive AFM images were recorded on a grounded Sb₂Se₃ sample using an atomic force microscopy (AFM, Park XE70). The topography and current images were simultaneously recorded in contact mode using a Pt/Ir coated contact probe (ANSCM-PT from AppNano, Inc.). The cantilever spring constant was about 3 N/m and resonance frequency was ˜60 KHz.

Solar Cell Measurement:

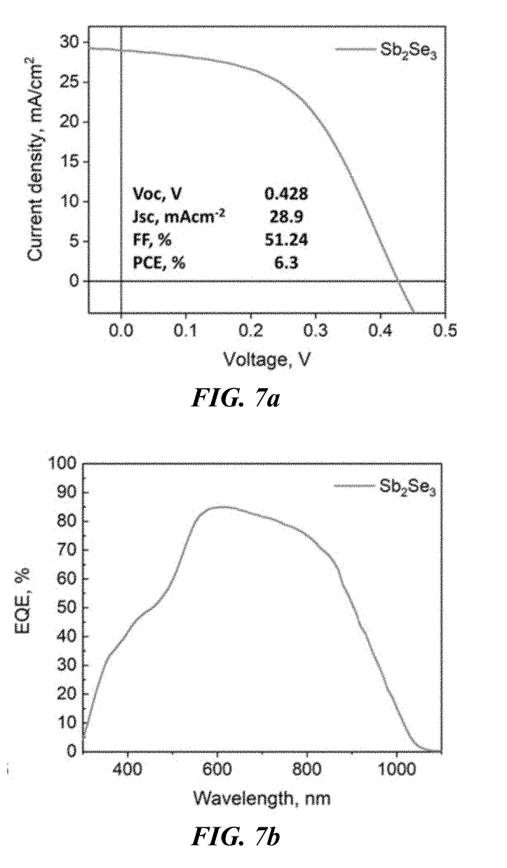

The finished solar cells current-voltage (J-V) curve were characterized using a solar simulator (Newport, Oriel Class AAA 94063A, 1000 Watt Xenon light source) with a source meter (Keithley 2420) at 100 mW/cm² AM 1.5 G irradiation. A calibrated Si-reference cell and meter (Newport, 91150V, certificated by NREL) was used to calibrate the solar simulator prior to each measurement. The EQE data were obtained by a solar cell spectral response measurement system (QE-T, Enli Tecnology, Co. Ltd). The current-voltage curves of two solar cells with different film thickness are shown in FIG. 7a with the corresponding EQE data being shown in FIG. 7b. The solar cells showed promising stability under ambient conditions.

Other advantages which are obvious and which are inherent to the invention will be evident to one skilled in the art. It will be understood that certain features and sub-combinations are of utility and may be employed without reference to other features and sub-combinations. This is contemplated by and is within the scope of the claims. Since many possible examples may be made of the invention without departing from the scope thereof, it is to be understood that all matter herein set forth or shown in the accompanying drawings is to be interpreted as illustrative and not in a limiting sense.

What is claimed is:

1. A thin film solar cell comprising:
a first electrode comprising a transparent conducting oxide;
a buffer layer disposed on the first electrode;
an antimony chalcogenide layer deposited via close spaced sublimation on the buffer layer, such that the buffer layer is disposed between the antimony chalcogenide layer and the first electrode; and
a second electrode in electrical contact with the antimony chalcogenide layer, such that the antimony chalcogenide layer is disposed between the second electrode and the buffer layer;
wherein the thin film solar cell has an efficiency of 4% or more.

2. The thin film solar cell of claim 1, wherein the transparent conducting oxide comprises indium doped tin oxide (ITO), fluorine doped tin oxide (FTO), aluminum doped ZnO (AZO), or a combination thereof.

3. The thin film solar cell of claim 1, wherein the buffer layer comprises a metal sulfide, a metal oxide, or a combination thereof.

4. The thin film solar cell of claim 1, wherein the buffer layer comprises CdS, SnO, ZnO, TiO₂ or a combination thereof.

5. The thin film solar cell of claim 1, wherein the buffer layer has an average thickness of from 20 nm to 1000 nm.

6. The thin film solar cell of claim 5, wherein the buffer layer has an average thickness of from 90 nm to 110 nm.

7. The thin film solar cell of claim 1, wherein the antimony chalcogenide layer comprises an antimony chalcogenide of the formula Sb₂SₓSe₃₋ₓ wherein x is any value from 0 to 3.

8. The thin film solar cell of claim 1, wherein the antimony chalcogenide layer comprises Sb₂Se₃, Sb₂S₃, or a combination thereof.

9. The thin film solar cell of claim 1, wherein the antimony chalcogenide layer has an average thickness of from 0.1 μm to 5 μm.

10. The thin film solar cell of claim 9, wherein the antimony chalcogenide layer has an average thickness of from 0.6 μm to 2 μm.

11. The thin film solar cell of claim 1, wherein the second electrode comprises graphite or Cu/Al.

12. The thin film solar cell of claim 1, wherein the thin film solar cell has an efficiency of from 4% to 32%.

13. A method of making the thin film solar cell of claim 1, the method comprising:
depositing the buffer layer on the first electrode;
depositing the antimony chalcogenide layer on the buffer layer via close spaced sublimation; and
disposing the second electrode on the antimony chalcogenide layer.

14. The method of claim 13, wherein the buffer layer is deposited by chemical bath deposition, physical vapor deposition, spray pyrolysis, or chemical vapor deposition.

15. The method of claim 13, further comprising annealing the buffer layer before depositing the antimony chalcogenide layer.

16. The method of claim 13, wherein an antimony chalcogenide source is used during the close spaced sublimation deposition, and wherein the antimony chalcogenide source has a temperature of from 200° C. to 350° C. during the close spaced sublimation deposition.

17. The method of claim 13, wherein the buffer layer deposited on the first electrode forms a coated electrode, and the antimony chalcogenide source has a temperature of from 450° C. to 600° C. during the close spaced sublimation deposition.

18. The method of claim 13, wherein the antimony chalcogenide layer is deposited via closed spaced sublimation at a pressure of from 1 mTorr to 100 mTorr.

19. The method of claim 13, wherein the antimony chalcogenide layer is deposited via close spaced sublimation for from 30 seconds to 120 seconds for various thickness.
